(19) United States
(12) Patent Application Publication
(10) Pub. No.: US 2010/0007018 A1
(43) Pub. Date: Jan. 14, 2010

(54) PROCESS FOR COATING A BUMPED SEMICONDUCTOR WAFER

(76) Inventors: DEREK WYATT, Corona, CA (US); Gyan Dutt, Garden Grove, CA (US); Albert P. Perez, La Habra, CA (US)

Correspondence Address: Henkel Corporation, 10 Finderne Avenue, Bridgewater, NJ, 08807, US

(21) Appl. No.: 12/480,153

(22) Filed: Jun. 8, 2009

Related U.S. Application Data
(63) Continuation of application No. PCT/US2006/047067, filed on Dec. 8, 2006.

(51) Int. Cl. H01L 21/31; H01L 23/498

(52) U.S. Cl. 257/737; 438/778; 257/E21.24; 257/E23.068

(57) ABSTRACT

A process is described that enables the active side of a bumped wafer to be coated with a front side protection (FSP) material or wafer level underfill (WLUF) without contaminating the solder bumps with the coating material and/or filler. In this process a repellent material is applied to a top portion of the solder bumps on the active side of the wafer, the front side of the wafer is then coated with the coating material, the coating material is hardened, and optionally the repellent material is removed from the solder bumps.

### CROSS-REFERENCE TO RELATED APPLICATION

This application is a continuation of International Application No. PCT/US2006/047067 filed Dec. 8, 2006, the contents of which are incorporated herein by reference.

### FIELD OF THE INVENTION

This invention relates to a process for coating bumped semiconductor wafers, as might be used to apply front side protection for wafer level packages (WLP) or wafer level underfill (WLUF) of flip chip devices.

### BACKGROUND OF THE INVENTION

Recent developments in packaging technology for semiconductor devices incorporate as many steps as possible at the wafer level. The application of materials prior to dicing and singulation of the wafer into individual dies results in an overall reduction in process time, and thus production costs. Often, the active surface of a wafer has deposited on it solder bumps that are later used to attach the individual die to bonding pads on a substrate, forming an electrical interconnection between the two. Numerous packaging processes have emerged which require the application of a paste or liquid coating to the bumped side of a wafer. Two examples of those processes include WLP for memory devices and WLUF for microprocessor and application specific integrated circuit (ASIC) devices.

Memory packages produced with WLP technology increasingly require a front side protection (FSP) coating. This is typically an adhesive or encapsulant that is applied to the active (bumped) side of the wafer and cured prior to dicing and singulation. As its name implies the FSP coating protects the active side of the wafer during subsequent processing steps such as dicing, singulation, and attach to the circuit board. Though not all memory devices packaged with WLP require an FSP coating, the need is becoming more prevalent with the evolution of this technology. Performance requirements such as the need for thinner packages, faster signal transfer, and increased memory capacity are leading to larger die that have smaller bump heights. These changes, separately and in combination, lead to increased package stress which is often mitigated with the use of an FSP coating.

Flip chip devices, especially those that have large die such as microprocessors or ASICs, are generally packaged with the use of an underfill, or encapsulant, around the solder bumps used to attach the active side of the die to the substrate or circuit board. Early technology in this package type utilized a capillary underfill, which was applied as a liquid to the periphery of a die that was already attached to the substrate. More recently, much work has been done to enable application of the underfills at the wafer level, so that the time-consuming capillary underfill step could be eliminated.

Coating of bumped semiconductor wafers can be done using a variety of techniques well known in the art including spin coating, stencil printing, and jetting. The spin coating process has the advantage of being very fast and, with the proper selection of coating material, giving a very uniform coating thickness. Furthermore, since there is no squeegee or other physical medium being scraped over the bumps, the coating may be applied at a thickness that is less than the height of the solder bumps and a solvent may or may not be used in the coating formulation.

However, when this method is used on a bumped surface the coating material not only coats the die, but also the tops of the solder bumps. The dies must then be attached using thermo-compression bonding, in which the solder joints are formed by applying heat and pressure during die placement. The heat and pressure expel the coating from the tops of the solder bumps, enabling a clean joint to be formed between the die and the substrate. This method is very time consuming, and thus expensive, and thermo-compression bonding equipment is not very prevalent in the industry. Furthermore, thermo-compression bonding is not sufficiently effective if there is filler on the solder bumps, so it cannot be used with coating formulations that contain significant amounts of filler. Alternatively, the coating material on the tops of the solder bumps may be removed before the die is attached to a substrate, so that the solder bumps can form a clean joint, yielding an effective interconnect to the adjoining substrate. This is especially necessary when the coating material contains filler, since filler particles on the bumps are particularly detrimental to joint formation.

Removal of the excess coating and/or filler particles can be done after cure and/or hardening of the coating, and is accomplished by either physical or chemical means including lapping, grinding, or chemical etching. Unfortunately, such process steps are time consuming, can damage the solder bumps or the wafer, and can lead to contamination. Therefore, it would be desirable to have a coating process that would coat the wafer to a prescribed thickness that is less than the solder bump height without significant coating residue on the solder bumps, so that no subsequent coating removal step would be necessary and standard “pick and place” die attach equipment (which has high throughput and is common in the industry) may be used.

Stencil printing is typically accomplished applying a solvent-based coating formulation at a thickness sufficient to cover the solder bumps. The coating is then B-staged, which is a process to evaporate the solvent and partially cure and/or harden the coating. The evaporation of the solvent provides substantial shrinkage of the coating, so that the resulting thickness of the coating is less than the height of the solder bumps. However, there is still significant residual coating on the tops of the bumps, and if the coating contains filler, there can also be filler particles on the bumps. In order for a clean solder joint to be formed with the substrate via pick-and-place die bonding, the coating and/or filler must be removed by physical or chemical means.

Alternatively, after dicing and singulation (separation of the dies after dicing), the dies can be attached to a substrate using a thermo-compression bonding, so that heat and pressure forces the residual coating out of the solder joint, enabling a good bond and electrical connection to be formed. As previously discussed, thermo-compression bonding equipment is currently not very prevalent in the industry, the process is a time-consuming method of attach, and is ineffective if there are filler particles on the bumps. Thus, it would be desirable to have a coating process that would enable application of the coating to the wafer at a prescribed thickness less than the solder bump height, and that does not result in a coating residue or filler particles on the tops of the solder bumps. Such a process would enable the use of traditional pick-and-place die attach equipment to assemble the packages, and filled coating formulations could more readily be used.

FIGS. 1 and 2 illustrate two traditional methods of wafer coating.

### SUMMARY OF THE INVENTION

This invention is a process for coating the active side of a semiconductor wafer which has solder bumps deposited thereon comprising:

(a) providing a semiconductor wafer having a front side which is active and has solder bumps deposited thereon and a back side opposed to the front side,

(b) applying a repellent material to a top portion of the solder bumps,

(c) coating the front side of the wafer with coating material,

(d) hardening the coating material, and

(e) optionally removing the repellent material from the bump.

This process enables the coating of a bumped wafer with either a filled or unfilled coating material to a prescribed thickness, which may be below the solder bump height, without the need to remove residual coating material from the bumps and without the need to utilize thermo-compression bonding to achieve clean solder joints.

In another embodiment this invention is a semiconductor wafer prepared according to the process described above.

### BRIEF DESCRIPTION OF THE FIGURES

The present invention can be more fully understood by reading the following detailed description, with reference made to the accompanying drawings, wherein:

FIG. 1 (Prior Art) illustrates the steps and corresponding wafer cross-sectional views, for a traditional wafer spin coating process.

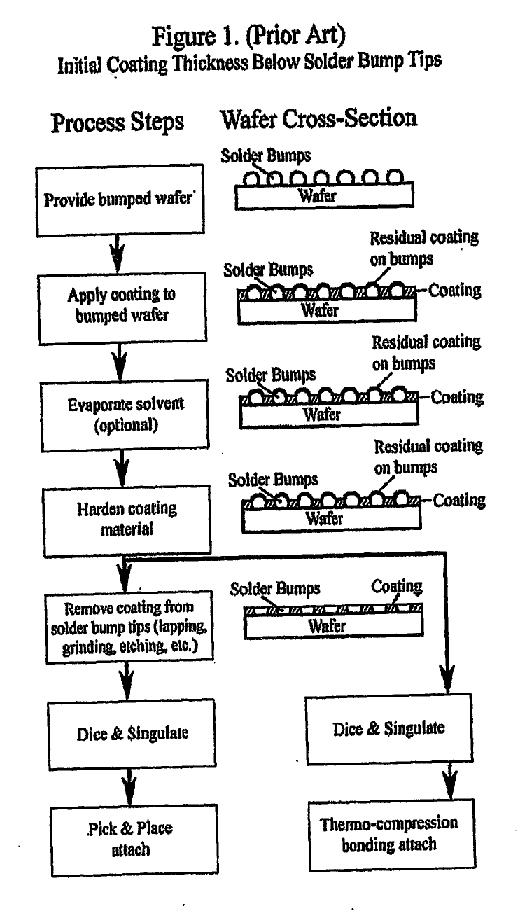

FIG. 2 (Prior Art) illustrates the steps and corresponding wafer cross-sectional views, for a traditional stencil print coating process.

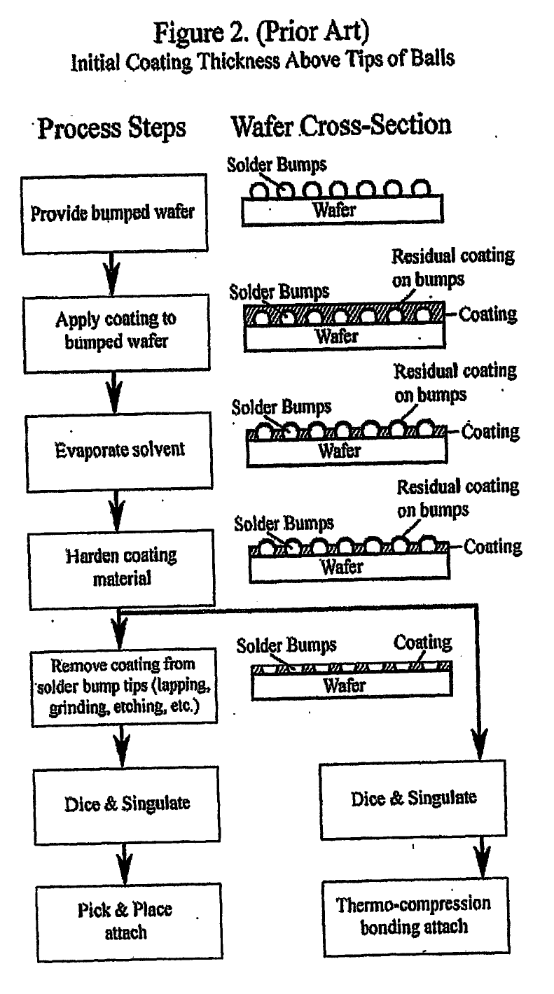

FIG. 3 illustrates an embodiment of the inventive process, in which the initial coating thickness is below the tips of the solder bumps.

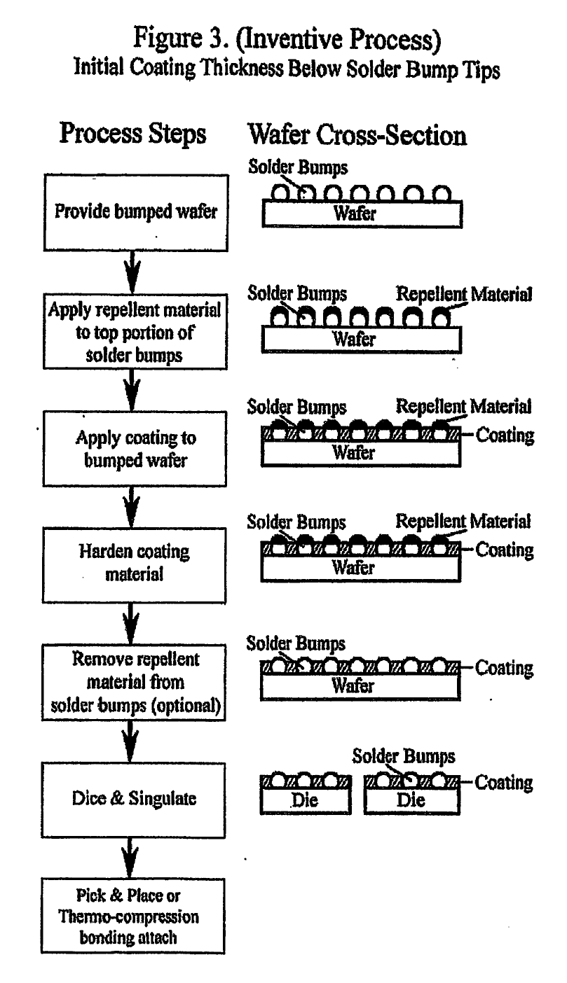

FIG. 4 illustrates an embodiment of the inventive process, in which the initial coating thickness is above the tips of the solder bumps.

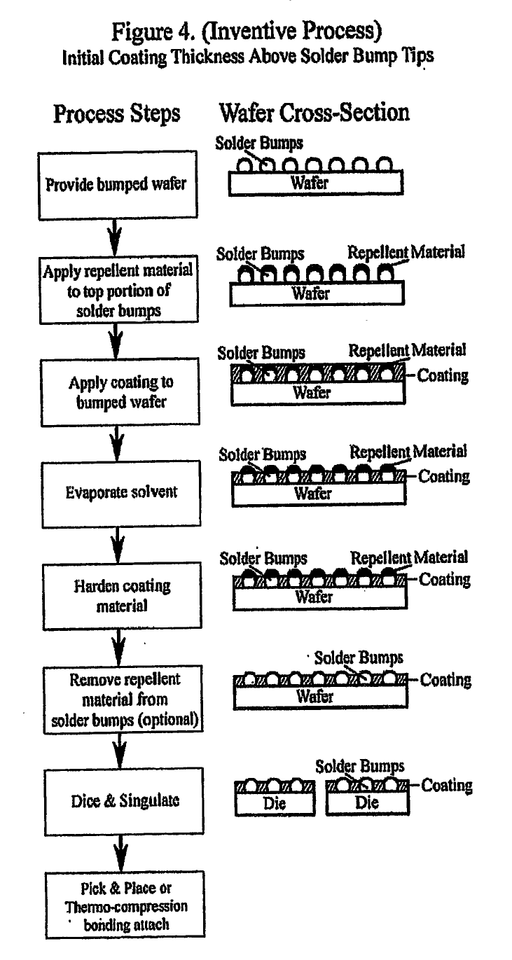

### DEFINITIONS

The term “alkyl” as used herein refers to a branched or un-branched saturated hydrocarbon group of 1 to 24 carbon atoms, such as methyl (“Me”), ethyl (“Et”), n-propyl, isopropyl, n-butyl, isobutyl, t-butyl, octyl, decyl, and the like. Preferred alkyl groups herein contain from 1 to 12 carbon atoms.

By the term “effective amount” of a compound, product, or composition as provided herein is meant a sufficient amount of the compound, product or composition to provide the desired results. As will be pointed out below, the exact amount required will vary from package to package, depending on the particular compound, product or composition used, its mode of administration, and the like. Thus, it is not always possible to specify an exact amount; however, an effective amount may be determined by one of ordinary skill in the art using only routine experimentation.

As used herein, the term “suitable” is used to refer to a moiety which is compatible with the compounds, products, or compositions as provided herein for the stated purpose. Suitability for the stated purpose may be determined by one of ordinary skill in the art using only routine experimentation.

As used herein, “substituted” is used to refer, generally, to a carbon or suitable heteroatom having a hydrogen or other atom removed and replaced with a further moiety. Moreover, it is intended that “substituted” refer to substitutions which do not change the basic and novel utility of the underlying compounds, products or compositions of the present invention.

As used herein, “B-staging” (and its variants) is used to refer to the processing of a material by heat or irradiation so that if the material is solubilized or dispersed in a solvent, the solvent is evaporated off with or without partial curing of the material, or if the material is neat with no solvent, the material is partially cured to a tacky or more hardened state. If the material is a flow-able adhesive, B-staging will provide extremely low flow without fully curing, such that additional curing may be performed after the adhesive is used to join one article to another. The reduction in flow may be accomplished by evaporation of a solvent, partial advancement or curing of a resin or polymer, or both.

### DETAILED DESCRIPTION OF THE INVENTION

The semiconductor wafer suitable for this invention can be of any diameter and any thickness and may comprise for instance silicon, gallium arsenide, indium phosphide, or any other semiconductor material. The semiconductor wafer is prepared with a top (front) surface, which is active where electronic elements and circuits are formed and a bottom (back) surface opposed to the active surface, which is inactive.

The front side of the wafer is electrically active and is bumped with solder bumps that will be later used to form electrical connections between the integrated circuit and a substrate. The solder bumps can be of any composition, size, and arrangement.

The repellent material works by repelling, or de-wetting, the coating material. The de-wetting or repellent effect may take place either during the application of the coating material to the wafer and/or during hardening of the coating material. The repellent material may be any substance that will stick to the solder bumps and is either physically or chemically incompatible with the coating material to be applied, and therefore will de-wet the coating material from the covered portion of the solder bump either during application of the coating or subsequent hardening of the coating material. Incompatibility, or the repellent characteristic, may be accomplished through either chemical or physical means. One method of achieving incompatibility is by using materials with a large difference in their surface energy (at least 5 mN/m).

In addition, there must not be a polar interaction between the repellent material and the coating material. For instance, if one of the materials is basic and the other is acidic there will be a polar attraction between them that will result in ineffective de-wetting. This can be true even if there is a large surface energy difference between the repellent material and the coating material.

Physical incompatibility may be accomplished with a repellent material that has an extremely smooth surface when hardened, such that the coating material is unable to physically adhere to the repellent material.

The melting point or softening point of the repellent material will be selected by the practitioner to be suitable for the particular coating material, cure profile, and process to be employed and typically ranges from −40° C. to 300° C. The repellent material may be either a solid or a liquid at room temperature, as long as its melting point is below the temperature to be used in the solder reflow process. In some cases the melting point or softening point may be selected to be below the B-stage temperature of the coating material, as long as it is high enough to allow for partial evaporation of the solvent and/or partial hardening or solidification of the resin before the repellent material melts and/or evaporates. In other situations it may be desirable to have a repellent material with a melting or softening point that is between the B-staging temperature and the cure temperature of the coating material so that the repellent material will remain fully in place during B-staging to protect the solder bumps, but will melt and possibly volatilize during thermal cure of the coating material. Alternatively, if the coating material is to be UV-cured the repellent material may have either a low or a high melting temperature, depending on the downstream process to be employed.

In one embodiment the repellent material is a wax. Suitable waxes may be natural or synthetic. Examples of suitable waxes include but are not limited to paraffin, parowax, microcrystalline waxes, petroleum wax blends, amorphous waxes, polyester waxes, soy wax, beeswax, and blends of those.

In another embodiment the repellent material is a low surface energy compound such as silane, polysiloxane, or a polyfluorinated compound.

In another embodiment the repellent material is dissolved in a solvent and the solvent/repellent material formulation is applied to the solder bumps. In this embodiment the repellent material is applied at either room temperature or an elevated temperature that is below the boiling point of the solvent. In a subsequent process step the solvent would be volatilized by the application of heat, leaving the repellent material coating the bumps.

The repellent material is applied to the tops of the solder bumps by any means that will allow for a controlled amount of material to be deposited to a controlled portion of the solder bump, without damaging the solder bumps or the wafer. In one embodiment the bumps are pressed into a pad that is soaked in melted repellent coating material. The pad may be a non-woven or woven material, fabric, sponge, or any similar material that would absorb the repellent material for transfer to the bumps. In another embodiment the bumps are dipped into a reservoir of melted repellent material. In both these embodiments the wafer is advanced into the reservoir or pad of repellent material such that the tops of the bumps are covered to a controlled portion of their overall height.

In another embodiment the repellent material is coated as a film onto a carrier such as paper, mylar, polyethylene, polypropylene, metal foil, etc. and is then laminated onto the bumps, giving a controlled thickness and coating depth. In another embodiment the repellent material is melted and then printed onto the tops of the bumps. In this embodiment a stencil or mask which has a pattern that matches the bump pattern on the wafer may be used, to ensure the wax is deposited to a controlled height on the tops of the bumps.

The portion of the bump that is to be covered will vary according to the specific package requirements and manufacturing conditions and can range from 5 to 100% of the overall bump height. Typically, when underfill is being applied, only a minimal amount of bump will be covered with the repellent material. This enables the underfill to encapsulate as much of the solder bumps as possible while still exposing enough solder bump surface for good joint formation with the substrate. In contrast, in a front side protection application the amount of bump that is covered with repellent material may be minimal to enable a thick coating of front side protection material, or a large portion of the bump may be covered if a very thin layer of front side protection material is required for the application.

Application of the repellent material can be done at any temperature suitable for the specific material set chosen, and can be determined by the practitioner without undue experimentation. For instance, if the repellent material is flow-able at room temperature it can be applied at room temperature. If the repellent material is hard at room temperature it will need to be heated so it can be softened or melted in order to apply it to the solder bumps without damaging them. The repellent material may also be heated to a temperature above room temperature but below the melting temperature of the material, such that the material is in a softened state that will enable application to the bumps by a rubbing or light contact process that will not damage the bumps, and such that the coating does not need to cool significantly to harden. This method would allow for a very controlled coating, without drips or runs that might be encountered with a fully liquefied repellent material. Furthermore, the wafer itself may be at room temperature or it may be heated to assist in the coating process, as required for the specific material set selected and manufacturing conditions employed.

The thickness, or depth, of the repellent material on the bumps will be selected by the practitioner to meet the needs of the specific manufacturing process and may range from a few microns to 100 microns. A thinner layer of repellent material would typically be desirable if a minimal wax residue were required. However, there may be situations where a thicker layer of repellent material would be desirable, for instance, to preserve an area for the expansion and collapse of the solder bump. This would occur when the coating is a front side wafer protection material. If the repellent material is coated as a thick layer on the whole bump, after volatilization of the repellent material, a vacant area around the bump would be created into which the bump could expand and collapse.

The depth or thickness of the repellent material layer may be controlled, in part, by the viscosity at application temperature. A material with a high viscosity at the application temperature will tend to give a thicker layer, whereas a material with a low viscosity at the application temperature will tend to give a thinner layer with less repellent material applied. The practitioner may change the amount of repellent material applied by changing a number of variables including the repellent material formulation, application temperature, pressure of application, or compressibility of the application medium.

Depending on whether the repellent material is in a flow-able state when it applied, there may be an additional process step in which the repellent material is hardened prior to the application of the coating material to the wafer. In the case where the repellent material is applied as a liquid, hardening of the repellent material may be required to prevent the coating material from physically removing the repellent material and contaminating the top portion of the bump. Furthermore, hardening the repellent material will prevent it from dripping down the surface of the bump toward the active side of the wafer, possibly preventing the coating material from properly encapsulating the bottom portion of the bumps. Typically the hardening would be accomplished by cooling the repellent material on the wafer.

The coating material may be any material that might be applied to the front side of a bumped die, including but not limited to, an adhesive, encapsulant, or front side protection material. Selection of a suitable coating material is dependent upon the purpose of the coating in the semiconductor package and the process to be employed. The coating typically will contain some type of polymer or curable resin, which could include a thermoplastic, a thermoset, an elastomer, a thermoset rubber, or a combination of these. The coating may or may not contain solvent. The polymer or curable resin will generally be a major component, excluding any fillers present.

Other components, typically used in coating compositions, may be added at the option of the practitioner; such other components include, but are not limited to, curing agents, fluxing agents, wetting agents, flow control agents, adhesion promoters, and air release agents. A curing agent is any material or combination of materials that initiate, propagate, or accelerate cure of the coating and includes accelerators, catalysts, initiators, and hardeners. The coating composition may also contain filler, in which case the filler will be present in an amount up to 95% of the total composition.

The viscosity and thixotropic index of the coating material will be selected by the practitioner to be suitable for the application method, manufacturing conditions and repellent material to be employed and is typically in the range of 100 to 60,000 cP as tested with a Brookfield CP 51 viscometer at 25° C. and 5 rpm. For instance, if the coating material is to be applied via spin coating the viscosity of the coating material would be fairly low. If the coating material will be applied with screen printing it will generally have a higher viscosity. In this situation the coating material might not de-wet from the solder bumps immediately upon coating of the wafer, due to its high viscosity and inability to flow. However, as the wafer is exposed to heat to either B-stage or cure the coating material, the viscosity of the coating material would drop before it starts to cure, enabling flow of the coating material and de-wetting from the solder bumps. In this situation the melting or softening point of the repellent material would be selected to be above the temperature at which the coating material would flow, so that it would remain in place to effect the de-wetting of the solder bumps.

Resins and polymers used in the coating may be solid, liquid, or a combination of the two. Suitable resins include epoxies, acrylates or methacrylates, maleimides, bismaleimides, vinyl ethers, polyesters, poly(butadienes), siliconized olefins, silicone resins, siloxanes, styrene resins and cyanate ester resins. In one embodiment the coating contains an epoxy resin, a bismaleimide resin, and an acrylate resin.

In one embodiment, solid aromatic bismaleimide (BMI) resin powders are included in the coating. Suitable solid BMI resins are those having the structure

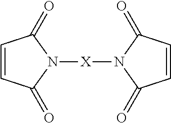

in which X is an aromatic group; exemplary aromatic groups include:

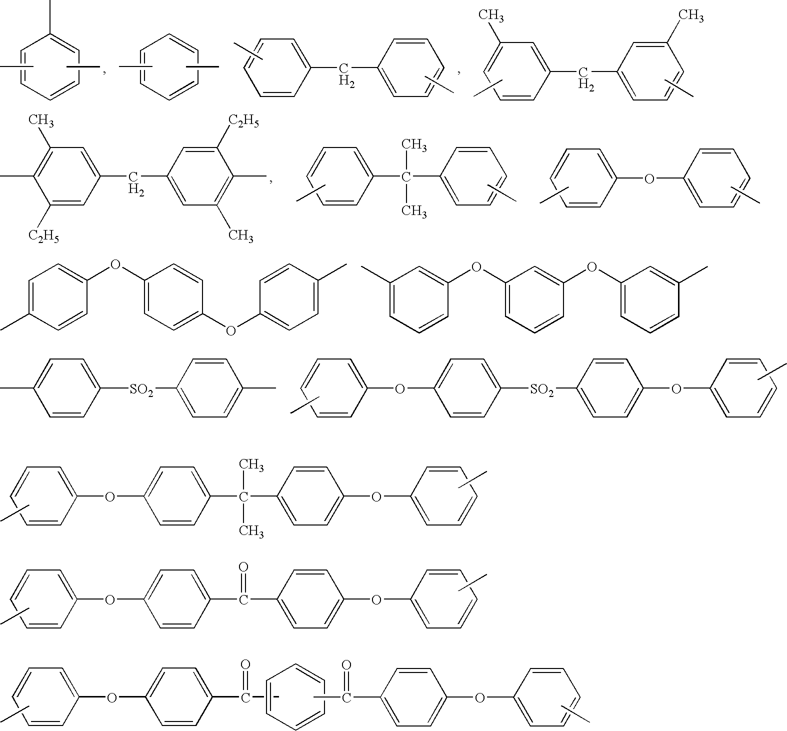

in which n is 1-3,

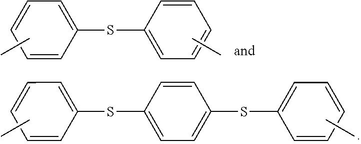

Bismaleimide resins having these X bridging groups are commercially available, and can be obtained, for example, from Sartomer (USA) or HOS-Technic GmbH (Austria).

In another embodiment, maleimide resins for use in the coating composition

include those having the generic structure

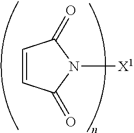

in which n is 1 to 3 and X¹ is an aliphatic or aromatic group. Exemplary X¹ entities include, poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. These types of resins are commercially available and can be obtained, for example, from National Starch and Chemical Company and Dainippon Ink and Chemical, Inc.

In a further embodiment, the maleimide resins are selected from the group consisting of

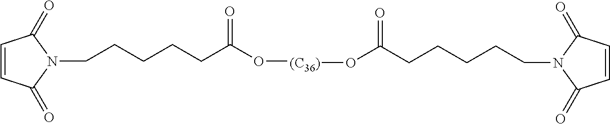

in which C₃₆ represents a linear or branched chain (with or without cyclic moieties) of 36 carbon atoms;

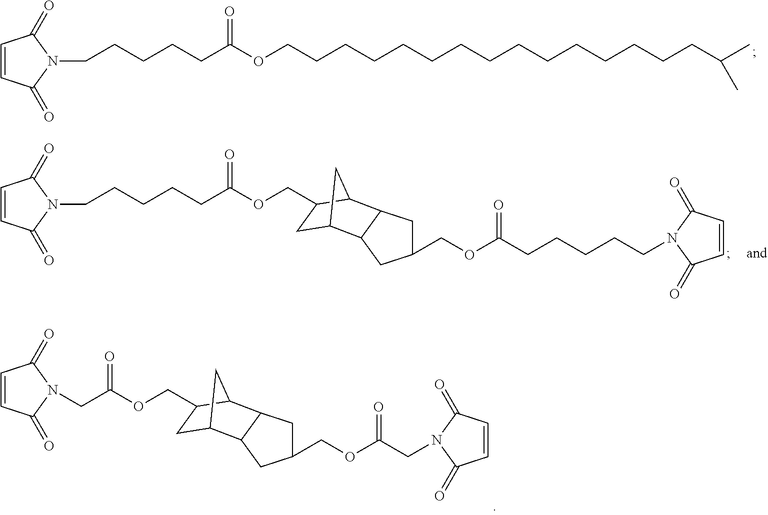

Suitable acrylate resins include those having the generic structure

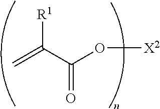

in which n is 1 to 6, R¹ is —H or —CH₃. and X² is an aromatic or aliphatic group. Exemplary X² entities include poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. Commercially available materials include butyl(meth)acrylate, isobutyl(meth)acrylate, 2-ethyl hexyl(meth)acrylate, isodecyl(meth)acrylate, n-lauryl(meth)acrylate, alkyl (meth)acrylate, tridecyl(meth)acrylate, n-stearyl(meth)acrylate, cyclohexyl(meth)acrylate, tetrahydrofurfuryl(meth)acrylate, 2-phenoxy ethyl(meth)acrylate, isobornyl(meth)acrylate, 1,4-butanediol di(meth)acrylate, 1.6 hexanediol di(meth)acrylate, 1,9-nonandiol di(meth)acrylate, perfluorooctylethyl(meth)acrylate, 1,10 decandiol di(meth)acrylate, nonylphenol polypropoxylate (meth)acrylate, and polypentoxylate tetrahydrofurfuryl acrylate, available from Kyoeisha Chemical Co., LTD; polybutadiene urethane dimethacrylate (CN302, NTX6513) and polybutadiene dimethacrylate (CN301, NTX6039, PRO6270) available from Sartomer Company, Inc; polycarbonate urethane diacrylate (ArtResin UN9200A) available from Negami Chemical Industries Co., LTD; acrylated aliphatic urethane oligomers (Ebecryl 230, 264, 265, 270, 284, 4830, 4833, 4834, 4835, 4866, 4881, 4883, 8402, 8800-20R, 8803, 8804) available from Radcure Specialities, Inc; polyester acrylate oligomers (Ebecryl 657, 770, 810, 830, 1657, 1810, 1830) available from Radcure Specialities, Inc.; and epoxy acrylate resins (CN104, 111, 112, 115, 116, 117, 118, 119, 120, 124, 136) available from Sartomer Company, Inc. In one embodiment the acrylate resins are selected from the group consisting of isobornyl acrylate, isobornyl methacrylate, lauryl acrylate, lauryl methacrylate, poly(butadiene) with acrylate functionality and poly(butadiene) with methacrylate functionality.

Suitable vinyl ether resins include those having the generic structure

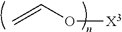

in which n is 1 to 6 and X³ is an aromatic or aliphatic group. Exemplary X³ entities include poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. Commercially available resins include cyclohenanedimethanol divinylether, dodecylvinylether, cyclohexyl vinylether, 2-ethylhexyl vinylether, dipropyleneglycol divinylether, hexanediol divinylether, octadecylvinylether, and butandiol divinylether available from International Specialty Products (ISP); Vectomer 4010, 4020, 4030, 4040, 4051, 4210, 4220, 4230, 4060, 5015 available from Sigma-Aldrich, Inc.

Suitable poly(butadiene) resins include poly(butadienes), epoxidized poly(butadienes), maleic poly(butadienes), acrylated poly(butadienes), butadiene-styrene copolymers, and butadiene-acrylonitrile copolymers. Commercially available materials include homopolymer butadiene (Ricon130, 131, 134, 142, 150, 152, 153, 154, 156, 157, P30D) available from Sartomer Company, Inc; random copolymer of butadiene and styrene (Ricon 100, 181, 184) available from Sartomer Company Inc.; maleinized poly(butadiene) (Ricon 130MA8, 130MA13, 130MA20, 131 MA5, 131 MA10, 131 MA17, 131 MA20, 156MA17) available from Sartomer Company, Inc.; acrylated poly(butadienes) (CN302, NTX6513, CN301, NTX6039, PRO6270, Ricacryl 3100, Ricacryl 3500) available from Sartomer Inc.; epoxydized poly(butadienes) (Polybd 600, 605) available from Sartomer Company. Inc. and Epolead PB3600 available from Daicel Chemical Industries, Ltd; and acrylonitrile and butadiene copolymers (Hycar CTBN series, ATBN series, VTBN series and ETBN series) available from Hanse Chemical.

Suitable epoxy resins include bisphenol, naphthalene, and aliphatic type epoxies. Commercially available materials include bisphenol type epoxy resins (Epiclon 830LVP, 830CRP, 835LV, 850CRP) available from Dainippon Ink & Chemicals, Inc.; naphthalene type epoxy (Epiclon HP4032) available from Dainippon Ink & Chemicals, Inc.; aliphatic epoxy resins (Araldite CY179, 184, 192, 175, 179) available from Ciba Specialty Chemicals, (Epoxy 1234, 249, 206) available from Union Carbide Corporation, and (EHPE-3150) available from Daicel Chemical Industries, Ltd. Other suitable epoxy resins include cycloaliphatic epoxy resins, bisphenol-A type epoxy resins, bisphenol-F type epoxy resins, epoxy novolac resins, biphenyl type epoxy resins, naphthalene type epoxy resins, dicyclopentadiene-phenol type epoxy resins, reactive epoxy diluents, and mixtures thereof.

Suitable siliconized olefin resins are obtained by the selective hydrosilation reaction of silicone and divinyl materials, having the generic structure,

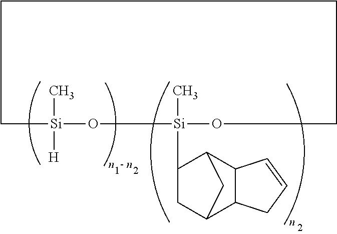

in which n₁ is 2 or more, n₂ is 1 or more and n₁>n₂. These materials are commercially available and can be obtained, for example, from National Starch and Chemical Company.

Suitable silicone resins include reactive silicone resins having the generic structure

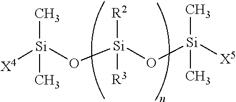

in which n is 0 or any integer, X⁴ and X⁵ are hydrogen, methyl, amine, epoxy, carboxyl, hydroxy, acrylate, methacrylate, mercapto, phenol, or vinyl functional groups, R² and R³ can be —H, —CH₃, vinyl, phenyl, or any hydrocarbon structure with more than two carbons. Commercially available materials include KF8012, KF8002, KF8003, KF-1001, X-22-3710, KF6001, X-22-164C, KF2001, X-22-170DX, X-22-173DX, X-22-174DX X-22-176DX, KF-857, KF862, KF8001, X-22-3367, and X-22-3939A available from Shin-Etsu Silicone International Trading (Shanghai) Co., Ltd.

Suitable styrene resins include those resins having the generic structure

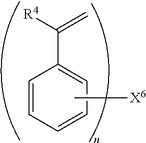

in which n is 1 or greater, R⁴ is —H or —CH₃, and X⁶ is an aliphatic group. Exemplary X³ entities include poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. These resins are commercially available and can be obtained, for example, from National Starch and Chemical Company or Sigma-Aldrich Co.

Suitable cyanate ester resins include those having the generic structure

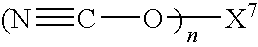

in which n is 1 or larger, and X⁷ is a hydrocarbon group. Exemplary X⁷ entities include bisphenol, phenol or cresol novolac, dicyclopentadiene, polybutadiene, polycarbonate, polyurethane, polyether, or polyester. Commercially available materials include; AroCy L-10, AroCy XU366, AroCy XU371, AroCy XU378, XU71787.02L, and XU 71787.07L, available from Huntsman LLC; Primaset PT30, Primaset PT30 S75, Primaset PT60, Primaset PT60S, Primaset BADCY, Primaset DA230S, Primaset MethylCy, and Primaset LECY, available from Lonza Group Limited; 2-allyphenol cyanate ester, 4-methoxyphenol cyanate ester, 2,2-bis(4-cyanatophenol)-1,1,1,3,3,3-hexafluoropropane, bisphenol A cyanate ester, diallylbisphenol A cyanate ester, 4-phenylphenol cyanate ester, 1,1,1-tris(4-cyanatophenyl)ethane, 4-cumylphenol cyanate ester, 1,1-bis(4-cyanateophenyl)ethane, 2,2,3,4,4,5,5,6,6,7,7-dodecafluorooctanediol dicyanate ester, and 4,4′-bisphenol cyanate ester, available from Oakwood Products, Inc.

Suitable polymers for the coating composition further include polyamide, phenoxy, polybenzoxazine, acrylate, cyanate ester, bismaleimide, polyether sulfone, polyimide, benzoxazine, vinyl ether, siliconized olefin, polyolefin, polybenzoxyzole, polyester, polystyrene, polycarbonate, polypropylene, poly(vinyl chloride), polyisobutylene, polyacrylonitrile, poly(methyl methacrylate), poly(vinyl acetate), poly(2-vinylpridine), cis-1,4-polyisoprene, 3,4-polychloroprene, vinyl copolymer, poly(ethylene oxide), poly(ethylene glycol), polyformaldehyde, polyacetaldehyde, poly(b-propiolacetone), poly(10-decanoate), poly(ethylene terephthalate), polycaprolactam, poly(1-undecanoamide), poly(m-phenylene-terephthalamide), poly(tetramethlyene-m-benzenesulfonamide), polyester polyarylate, poly(phenylene oxide), poly(phenylene sulfide), polysulfone, polyimide, polyetheretherketone, polyetherimide, fluorinated polyimide, polyimide siloxane, poly-iosindolo-quinazolinedione, polythioetherimide poly-phenyl-quinoxaline, polyquuinixalone, imide-aryl ether phenylquinoxaline copolymer, polyquinoxaline, polybenzimidazole, polybenzoxazole, polynorbornene, poly(arylene ethers), polysilane, parylene, benzocyclobutenes, hydroxy(benzoxazole) copolymer, poly(silarylene siloxanes), and polybenzimidazole.

Other suitable materials for inclusion in coating compositions include rubber polymers such as block copolymers of monovinyl aromatic hydrocarbons and conjugated diene, e.g., styrene-butadiene, styrene-butadiene-styrene (SBS), styrene-isoprene-styrene (SIS), styrene-ethylene-butylene-styrene (SEBS), and styrene-ethylene-propylene-styrene (SEPS).

Other suitable materials for inclusion in coating compositions include ethylene-vinyl acetate polymers, other ethylene esters and copolymers, e.g., ethylene methacrylate, ethylene n-butyl acrylate and ethylene acrylic acid; polyolefins such as polyethylene and polypropylene; polyvinyl acetate and random copolymers thereof; polyacrylates; polyamides; polyesters; and polyvinyl alcohols and copolymers thereof.

Suitable thermoplastic rubbers include carboxy terminated butadiene-nitrile (CTBN)/epoxy adduct, acrylate rubber, vinyl-terminated butadiene rubber, and nitrile butadiene rubber (NBR). In one embodiment the CTBN epoxy adduct consists of about 20-80 wt % CTBN and about 20-80 wt % diglycidyl ether bisphenol A: bisphenol A epoxy (DGEBA). A variety of CTBN materials are available from Noveon Inc., and a variety of bisphenol A epoxy materials are available from Dainippon Ink and Chemicals, Inc., and Shell Chemicals. NBR rubbers are commercially available from Zeon Corporation.

Suitable siloxanes include elastomeric polymers comprising a backbone and pendant from the backbone at least one siloxane moiety that imparts permeability, and at least one reactive moiety capable of reacting to form a new covalent bond. Examples of suitable siloxanes include elastomeric polymers prepared from: 3-(tris(trimethylsilyloxy)silyl)-propyl methacrylate, n-butyl acrylate, glycidyl methacrylate, acrylonitrile, and cyanoethyl acrylate; 3-(tris(trimethylsilyloxy)silyl)-propyl methacrylate, n-butyl acrylate, glycidyl methacrylate, and acrylonitrile; and 3-(tris(trimethylsilyloxy)silyl)-propyl methacrylate, n-butyl acrylate, glycidyl methacrylate, and cyanoethyl acrylate.

If curing agent is required, its selection is dependent on the polymer chemistry used and the processing conditions employed. As curing agents, the compositions may use aromatic amines, alycyclic amines, aliphatic amines, tertiary phosphines, triazines, metal salts, aromatic hydroxyl compounds, or a combination of these. Examples of such catalysts include imidazoles, such as 2-methylimidazole, 2-undecylimidazole, 2-heptadecyl imidazole, 2-phenylimidazole, 2-ethyl 4-methylimidazole, 1-benzyl-2-methylimidazole, I-propyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-guanaminoethyl-2-methylimidazole and addition product of an imidazole and trimellitic acid; tertiary amines, such as N,N-dimethyl benzylamine, N,N-dimethylaniline, N,N-dimethyltoluidine, N,N-dimethyl-p-anisidine, p-halogeno-N,N-dimethylaniline, 2-N-ethylanilino ethanol, tri-n-butylamine, pyridine, quinoline, N-methylmorpholine, triethanolamine, triethylenediamine, N,N,N′,N′-tetramethylbutanediamine, N-methylpiperidine; phenols, such as phenol, cresol, xylenol, resorcine, and phloroglucin; organic metal salts, such as lead naphthenate, lead stearate, zinc naphthenate, zinc octolate, tin oleate, dibutyl tin maleate, manganese naphthenate, cobalt naphthenate, and acetyl aceton iron; and inorganic metal salts, such as stannic chloride, zinc chloride and aluminum chloride; peroxides, such as benzoyl peroxide, lauroyl peroxide, octanoyl peroxide, acetyl peroxide, para-chlorobenzoyl peroxide and di-t-butyl diperphthalate; acid anhydrides, such as carboxylic acid anhydride, maleic anhydride, phthalic anhydride, lauric anhydride, pyromellitic anhydride, trimellitic anhydride, hexahydrophthalic anhydride; hexahydropyromellitic anhydride and hexahydrotrimellitic anhydride, azo compounds, such as azoisobutylonitrile, 2,2′-azobispropane, m,m′-azoxystyrene, hydrozones, and mixtures thereof.

In one embodiment, a curing accelerator may be selected from the group consisting of triphenylphosphine, alkyl-substituted imidazoles, imidazolium salts, onium salts, quartenary phosphonium compounds, onium borates, metal chelates, 1,8-diazacyclo[5.4.0]undex-7-ene or a mixture thereof.

In another embodiment the curing agent can be either a free radical initiator or cationic initiator, depending on whether a radical or ionic curing resin is chosen. If a free radical initiator is used, it will be present in an effective amount. An effective amount typically is 0.1 to 10 percent by weight of the organic compounds (excluding any filler). Appropriate free-radical initiators include peroxides, such as butyl peroctoates and dicumyl peroxide, and azo compounds, such as 2,2′-azobis(2-methyl-propanenitrile) and 2,2′-azobis(2-methyl-butanenitrile).

If a cationic initiator is used, it will be present in an effective amount. An effective amount typically is 0.1 to 10 percent by weight of the organic compounds (excluding any filler). Preferred cationic curing agents include dicyandiamide, phenol novolak, adipic dihydrazide, diallyl melamine, diamino malconitrile, BF3-amine complexes, amine salts and modified imidazole compounds.

Metal compounds also can be employed as cure accelerators for cyanate ester systems and include, but are not limited to, metal napthenates, metal acetylacetonates (chelates), metal octoates, metal acetates, metal halides, metal imidazole complexes, and metal amine complexes.

Other cure accelerators that may be included in the coating formulation include triphenylphosphine, alkyl-substituted imidazoles, imidazolium salts, and onium borates.

In some cases, it may be desirable to use more than one type of cure. For example, both cationic and free radical initiation may be desirable, in which case both free radical cure and ionic cure resins can be used in the composition. These compositions would contain effective amounts of initiators for each type of resin. Such a composition would permit, for example, the curing process to be started by cationic initiation using UV irradiation, and in a later processing step, to be completed by free radical initiation upon the application of heat.

If the coating material contains solvent it will typically require a drying and/or B-staging step. The time and temperature required to achieve this will vary according to the solvent and coating composition used and can be determined by the practitioner without undue experimentation. The drying and/or B-staging may be done as a step separate from the curing of the coating (if the coating will be cured), or it may be done as a separate process step.

If the coating material does not contain solvent it may still be desirable to B-stage, or partially advance, the coating material. This may be done prior to cure to effect hardening of the coating to a non-tacky state so that additional processing may be done before the coating is fully cured.

The coating may or may not require curing, depending on the purpose and composition of the coating. If the coating does require curing the cure may be accomplished either as an individual process step, or in conjunction with another processing operation such as solder reflow. The cure may be done at the wafer level or at the die level, depending on the purpose of the coating, the composition of the coating, and the manufacturing process employed.

If a curing step is utilized, the cure temperature will generally be within a range of 80°-250° C., and curing will be effected within a time period ranging from few seconds or up to 120 minutes, depending on the particular resin chemistry and curing agents chosen. The time and temperature curing profile for each coating composition will vary, and different compositions can be designed to provide the curing profile that will be suited to the particular industrial manufacturing process.

Depending on the end application, one or more fillers may be included in the coating composition and usually are added for improved rheological properties and stress reduction. For coating of the active side of a wafer the filler will be electrically nonconductive. Examples of suitable nonconductive fillers include alumina, aluminum hydroxide, silica, vermiculite, mica, wollastonite, calcium carbonate, titania, sand, glass, barium sulfate, zirconium, carbon black, organic fillers, and halogenated ethylene polymers, such as, tetrafluoroethylene, trifluoroethylene, vinylidene fluoride, vinyl fluoride, vinylidene chloride, and vinyl chloride. The filler particles may be of any appropriate size ranging from nano size to several mm. The choice of such size for any particular end use is within the expertise of one skilled in the art. Filler may be present in an amount from 0 to 95% by weight of the total composition.

In one embodiment, a fluxing agent is added to the coating composition. The fluxing agent primarily removes metal oxides and prevents reoxidation of the solder bumps. Fluxing agent selection will depend on the resin chemistry and bump metallurgy utilized. However, some of the key requirements of the fluxing agent are that it should not affect the curing of the coating resin, should not be too corrosive, should not outgass too much during reflow, should be compatible with the resin, and/or the flux residues should be compatible with the resin.

Examples of suitable fluxing agents include compounds that contain one or more hydroxyl groups (—OH), or carboxylic (—COOH) group or both, such as organic carboxylic acids, anhydrides, and alcohols, for example, rosin gum, dodecanedioic acid (commercially available as Corfree M2 from Aldrich), sebasic acid, polysebasic polynhydride, maleic acid, hexahydrophthalic anhydride, methyl hexahydrophthalic anhydride, ethylene glycol, glycerin, tartaric acid, adipic acid, citric acid, malic acid, glutaric acid, glycerol, 3-[bis(glycidyl oxy methyl)methoxy]-1,2-propane diol, D-ribose, Dcellobiose, cellulose, 3-cyclohexene-1,1-dimethanol; amine fluxing agents, such as, aliphatic amines having 1-10 carbon atoms, e.g., trimethylamine, triethylamine, n-propylamine, n-butylamine, isobutylamine, sec-butylamine, t-butylamine, n-amylamine, sec-amylamine, 2-ethylbutylamine, n-heptylamine, 2-ethylhexylamine, n-octylamine, and t-octylamine; epoxy resins employing a cross-linking agent with fluxing properties. Other fluxing agents include organic alcohols. Fluxing agents may also be compounds having (i) an aromatic ring, (ii) at least one —OH, —NHR (where R is hydrogen or lower alkyl), or —SH group, (iii) an electron-withdrawing or electron-donating substituent on the aromatic ring, and (iv) no imino group. Fluxing agents will be present in an effective amount; typically, an effective amount ranges from 1 to 30% by weight.

In another embodiment, a coupling agent may be added to the coating composition. Typically, coupling agents are silanes, for example, epoxy-type silane coupling agent, amine-type silane coupling agent, or mercapto-type silane coupling agent. Coupling agents, if used, will be used in an effective amount. A typical effective amount is an amount up to 5% by weight.

In a further embodiment, a surfactant may be added to the coating composition. Suitable surfactants include organic acrylic polymers, silicones, polyethylene glycol, polyoxyethylene/polyoxypropylene block copolymers, ethylene diamine based polyoxyethylene/polyoxypropylene block copolymers, polyol-based polyoxyalkylenes, fatty alcohol-based polyoxyalkylenes, fatty alcohol polyoxyalkylene alkyl ethers, and mixtures thereof. Surfactants, if used, will be used in an effective amount: a typical effective amount is an amount up to 5% by weight.

In another embodiment a wetting agent may be included in the coating composition. Wetting agent selection will depend on the application requirements and the resin chemistry utilized. Wetting agents, if used, will be used in an effective amount: a typical effective amount is up to 5% by weight. Examples of suitable wetting agents include Fluorad FC-4430 Fluorosurfactant available from 3M, Clariant Fluowet OTN, BYK W-990, Surfynol 104 Surfactant, Crompton Silwet L-7280, Triton X100 available from Rhom and Haas, Propylene glycol with a preferable Mw greater than 240, Gama-Butyrolactone, castor oil, glycerin or other fatty acids, and silanes.

In a further embodiment, a flow control agent may be included in the coating composition. Flow control agent selection will depend on the application requirements and resin chemistry employed. Flow control agents, if used, will be present in an effective amount: an effective amount is an amount up to 5% by weight. Examples of suitable flow control agents include Cab-O-Sil TS720 available from Cabot, Aerosil R202 or R972 available from Degussa, fumed silicas, fumed aluminas, or fumed metal oxides.

In another embodiment, an adhesion promoter may be included in the coating composition. Adhesion promoter selection will depend on the application requirements and resin chemistry employed. Adhesion promoters, if used, will be used in an effective amount: an effective amount is an amount up to 5% by weight. Examples of suitable adhesion promoters include: silane coupling agents such as Z6040 epoxy silane or Z6020 amine silane available from Dow Corning; A186 Silane, A187 Silane, A174 Silane, or A1289 available from OSI Silquest; Organosilane S1264 available from Degussa; Johoku Chemical CBT-1 Carbobenzotriazole available from Johoku Chemical; functional benzotriazoles; thiazoles; titanates; and zirconates.

In a further embodiment, an air release agent (defoamer) may be added to the coating formulation. Air release agent selection will depend on the application requirements and resin chemistry employed. Air release agents, if used, will be used in an effective amount: an effective amount will be an amount up to 5% by weight. Examples of suitable air release agents include Antifoam 1400 available from Dow Corning, DuPont Modoflow, and BYK A-510.

In some embodiments these compositions are formulated with tackifying resins in order to improve adhesion and introduce tack; examples of tackifying resins include naturally-occurring resins and modified naturally-occurring resins; polyterpene resins; phenolic modified terpene resins; coumarons-indene resins; aliphatic and aromatic petroleum hydrocarbon resins; phthalate esters; hydrogenated hydrocarbons, hydrogenated rosins and hydrogenated rosin esters.

In some embodiments other components may be included, for example, diluents such as liquid polybutene or polypropylene; petroleum waxes such as paraffin and microcrystalline waxes, polyethylene greases, hydrogenated animal, fish and vegetable fats, mineral oil and synthetic waxes, naphthenic or paraffinic mineral oils.

In some embodiments, monofunctional reactive diluents can be included to incrementally delay an increase in viscosity without adversely affecting the physical properties of the cured coating. Suitable diluents include p-tert-butyl-phenyl glycidyl ether, allyl glycidyl ether, glycerol diblycidyl ether, glycidyl ether of alkyl phenol (commercially available from Cardolite Corporation as Cardolite NC513), and Butanediodiglycidylether (commercially available as BDGE from Aldrich), although other diluents may be utilized.

Other additives, such as stabilizers, antioxidants, impact modifiers, and colorants, in types and amounts known in the art, may also be added to the coating material formulation.

Common solvents that readily dissolve the resins, and with a proper boiling point ranging from 25° C. to 200° C. can be used for this application. Examples of solvents that may be utilized include ketones, esters, alcohols, ethers, and other common solvents that are stable. Suitable solvents include γ-butyrolactone, propylene glycol methyl ethyl acetate (PGMEA), and 4-methyl-2-pentanone.

If the coating is curable it may be cured by thermal exposure, ultraviolet (UV) irradiation, microwave, or a combination of these. Curing conditions will be tailored to the coating formulation and will be readily determined by the practitioner. Furthermore the coating may be B-stage-able or not, depending on the application requirements.

The front side, or active side, of the wafer is coated by any means suitable for uniformly applying material to a bumped wafer, including but not limited to stencil printing, spin coating, curtain coating, meniscus coating, or jet dispensing. Coating temperature, pressure, speed, and other coating conditions will be dictated by the method used and the coating to be applied and can be determined by the skilled practitioner without undue experimentation. The coating material is applied to the wafer to a thickness that may be either below, at, or above the height of the solder bumps, depending upon the application method employed, the coating material used, and the requirements of the specific semiconductor package. In the case of a coating material that does not contain solvent the coating thickness will typically be equivalent to the height of the exposed portion of the bumps. In the case of a coating material that does contain solvent the wet coating thickness will typically be higher than the exposed portion of the solder bumps, i.e. it will partially or completely cover the repellent material. After the solvent is removed the final coating thickness will typically be equivalent to the exposed portion of the solder bumps.

The coating material is hardened to enable subsequent processing steps including backgrinding, application of backside protection materials, dicing, singulation, and die attach. The hardening method employed will depend upon the coating material chosen and the manufacturing process employed. In the case of a thermoplastic coating the coated wafer is cooled to a temperature below the melting point of the thermoplastic. In the case of a B-stage-able coating hardening will be accomplished by B-staging the coating with either heat or UV radiation. Thermoset coating materials are hardened by exposure to heat and/or UV radiation to effect curing of the coating. The conditions required to harden the coating are readily determined by the skilled practitioner without undue experimentation.

Optionally, once the coating has been hardened the repellent material may be removed from the upper surface of the bumps. Typically, the removal will be accomplished by melting and/or volatilizing the repellent material with heat. When a thermally B-stage-able and/or thermally curable coating material has been used the removal of the repellent material may be done in the same heating process as is used to harden the coating material, or in a separate heating step. Depending on the bump metallurgy, package configuration, repellent material properties, and attach equipment utilized it may not be necessary to remove the repellent material prior to die attach and solder bump reflow. In some cases, such as with thermo compression bonding, the repellent material will be physically displaced by heat, pressure, or a combination of the two when the die is attached to a substrate and the solder joint is formed. The repellent material could also be removed by plasma cleaning (etching with an ionized gas) or by cleaning in an ultrasonic bath with a surfactant or soap.

After the coating is hardened the wafer is diced and singulated into individual die by traditional processes. The coated die may be attached by any traditional means, including pick and place and thermo compression bonding. In the case of pick and place, either solder-on-pad or flux-on-pad bonding may be done to aid with alignment and fluxing during reflow.

### EXAMPLES

Examples 1-5 were prepared using a coating formulation that contained 13 wt % bisphenol-A epoxy, 22 wt % gamma-butyrolactone and 51 wt % silica filler. The remaining 14 wt % of the coating formulation was a combination of curing agents, adhesion promoters, and other additives commonly used in adhesive formulations. The coating had a viscosity of 5100 cP and a thixotropic index of 1.5. A wafer was coated using spin coating without the inventive process (i.e. without applying a repellent material to the top portion of the bumps) and is presented as Comparative Example 1. The inventive process was used for Examples 2 through 4. In Example 2a wafer with 240 micron bumps was used and the full surface of the bumps was covered with repellent material. In Example 3 the bumps were 130 microns and repellent material was applied only to the top portion of the bumps. In Example 4 the bumps were 450 microns high and repellent material was applied to the top 200 microns of bump height. In Example 5 three waxes were tested for surface energy characteristics, and their relative de-wetting performance using the inventive process was compared.

### Comparative Example 1

### Without Repellent Material

A 6″ silicon wafer which was 450 micron thick and bumped with Sn/Ag/Cu bumps 240-microns in height arranged at 300 micron pitch was spin-coated coated with the solvent-based epoxy material to a depth of 200 microns. The spin coating was performed at room temperature under N₂ atmosphere with a profile of a spread cycle at 350 rpm for 15 seconds followed by 5 seconds at 800 rpm. The solvent was removed by a B-stage step at 135° C. for 20 minutes, resulting in the formation of a hardened, non-tacky coating. The wafer and bumps were then examined with SEM with a backscattered electron detector. The bumps were almost completely covered with the coating material, which appeared black in the SEM image, with just a small amount of solder bumps showing as white in color.

### Example 2

### Inventive Process (with Repellent Material)

A 6″ silicon wafer which was 450 micron thick and bumped with Sn/Ag/Cu bumps 240-microns in height arranged at 300 micron pitch was prepared according to the inventive process. The repellent material utilized was a paraffin wax, sold under the trade name Parowax, which had a melting point of 53° C. The repellent material was applied in such a way as to cover the full surface area of the bumps by pressing the bumped side of the wafer against a paper pad saturated with the paraffin wax at 135° C. The depth of the press was controlled by shims. The wax hardened by cooling to room temperature to form a smooth coating on the bumps. The wafer and bumps were then examined with SEM with a backscattered electron detector at 45× to 150× magnification. The wax had covered the solder bumps and appeared black in the image. The front (bumped) side of the wafer was spin-coated coated with the solvent-based epoxy material. The spin coating was performed at room temperature under N₂ atmosphere with a profile of a spread cycle at 350 rpm for 150 seconds followed by 5 seconds at 800 rpm. The solvent was removed by a B-stage step at 135° C. for 20 minutes, resulting in the formation of a hardened non-tacky coating 190 microns thick (measuring from the surface of the wafer up). The B-stage also melted the wax and exposed the bumps with minimal residue of wax on the tips of the solder bumps. The wafer and bumps were then examined with SEM with a backscattered electron detector at 45× to 150× magnification. The bumps were almost completely exposed (appearing white in the SEM image), with minimal wax or coating residue visible (which appeared black in the SEM image).

### Example 3

### Inventive Process (with Repellent Material)

A 6″ silicon wafer which was 450 micron thick and bumped with Sn63/37Pb bumps 130-microns in height arranged at 190 micron pitch was prepared according to the inventive process. The repellent material utilized was a paraffin wax, sold under the trade name Parowax, which had a melting point of 53° C. The repellent material was applied to the top portion of the solder balls to a depth of 50 microns (measured from the top of the bump down towards the wafer) by pressing the bumped side of the wafer against a paper pad saturated with the paraffin wax at 135° C. The depth of the press was controlled by shims. The wax hardened by cooling to room temperature to form a smooth coating on the bumps. The wafer and bumps were then examined with SEM with a backscattered electron detector at 150× magnification. The wax had covered the top portion of the solder bumps and appeared black in the image, and the solder bumps appeared white. The front (bumped) side of the wafer was then spin-coated coated with the solvent-based epoxy material. The spin coating was performed at room temperature under N₂ atmosphere with a profile of a spread cycle at 800 rpm for 60 seconds followed by 30 seconds at 1200 rpm. The solvent was removed by a B-stage step at 135° C. for 20 minutes, resulting in the formation of a hardened non-tacky coating 90 microns thick (measured from the surface of the wafer up). The B-stage also melted the wax and exposed the bumps with minimal residue of wax on the tips of the balls. The wafer and bumps were then examined with SEM with a backscattered electron detector at 150× magnification. The bumps were almost completely exposed (appearing white in the SEM image), with minimal wax or coating residue visible (which appeared black in the SEM image).

### Example 4

### Inventive Process (with Repellent Material)

A single bumped silicon die which was measured to be 450 micron thick and bumped with Sn/Ag/Cu bumps measured to be 475 microns in height arranged at 800 micron pitch was prepared according to the inventive process. The repellent material utilized was a paraffin wax, sold under the trade name Parowax, which had a melting point of 53° C. The repellent material was applied to a depth of approximately 200 microns (measured from the top of the bump down towards the die) by manually pressing the bumped side of the die against a paper pad saturated with the paraffin wax at 100° C. The wax hardened by cooling to room temperature to form a smooth coating on the bumps. The die and bumps were then examined with SEM with a backscattered electron detector at 35× magnification. The wax had covered the tips of the solder bumps and appeared black in the image, and the solder bumps appeared white. The front (bumped) side of the die was spin-coated with the solvent-based epoxy material. The spin coating was performed at room temperature under ambient atmosphere with a profile of a spread cycle at 350 rpm for 150 seconds followed by 5 seconds at 800 rpm. The solvent was removed by a B-stage step at 135° C. for 30 minutes, resulting in the formation of a hardened non-tacky coating. The B-stage process also melted the wax and exposed the bumps with minimal residue of wax on the tip of the solder bumps. The wafer and bumps were then examined with SEM with a backscattered electron detector at 35× magnification. The bumps were almost completely exposed (appearing white in the SEM image), with minimal wax or coating residue visible (which appeared black in the SEM image).

### Example 5

### Surface Energy Characterization

The effectiveness of the repellent material in causing de-wetting of the coating material from the bumps is influenced by both dispersive, (or non-polar) and polar interactions between the coating material and the repellent material. The effects of these interactions were identified and quantified by performing full surface energy characterization of the materials.

A Kruss Tensiometer was used to measure contact angles for surface energy calculations. Contact angle measurements were done on three repellent materials (paraffin wax Parowax, Clarus CSX Microblend 35, and Accublend M300) using liquids of known surface energies. The liquids used were de-ionized water, hexane, glycerol, hexyl ester bismaleimide, and methyl-ethyl ketone. The repellent materials were cast in 2 cm thick, flat, circular discs. Sessile drops of the liquids (<2 mm diameter) were placed on the surface of the discs, on the sample stage of the Kruss Tensiometer. All measurements were performed at room temperature. A CCD video camera module camera was used to image the liquid drop on the disc surface. Kruss' Drop Shape Analysis software was used to detect the baseline and measure the contact angle by using the Tangent-1 method. The measured contact angles are presented in Table 1.

TABLE 1
Contact angle measurements of various liquids on different
repellent material surfaces

| | Water | Glycerol | Hexane | MEK | SRM-1 |
|---|---|---|---|---|---|
| Parowax | 108.6 | 109.2 | 0 | 28.4 | 64.5 |
| AccuBlend M-300 | 91.2 | 100.2 | 0 | 3.3 | 55.2 |
| Microblend | 101.6 | 94.2 | 0 | 3.12 | 54.9 |

Similarly, the solvent-based epoxy coating material (Material A) used in Examples 1-3 was tested for contact angle on the following substrates of known surface properties: glass, silicon, bismaleimide-triazine (BT), nylon 66, and polyethylene. Sessile drops of Material A (uncured) were placed on these substrates on the Kruss Tensiometer sample stage at room temperature and contact angles were measured. The contact angles are presented in Table 2.

TABLE 2
Contact angle measurements of Material A on substrates
with known surface properties

| | | Silicon | | | |
|---|---|---|---|---|---|
| | Glass | Polished | BT | Nylon | Polyethylene |
| Material A | 43.9 | 35.7 | 50.9 | 42 | 71.2 |

The contact angle measurements were used to calculate surface properties. The total surface energy was broken down into non-polar dispersive component (denoted by γ^{LW}) and polar components (γ⁺ for acidic and γ⁻ for basic). Using the measured contact angle between a liquid (L) and a solid (S) of θ, the following equation was used to relate the contact angle and solid/liquid surface properties:

½γ_{L}(1+cos θ)=(γ_{L}^{LW}γ^{LW}_{S})^{1/2}+(γ_{S}⁻γ_{L}⁺)^{1/2}

In this example, the surface properties (γ^{LW}, γ⁺ and γ⁻) of either the solid or liquid were known, and the contact angle θ was measured, for at least three measurements with liquids/solids of known properties. This allowed for the calculation of the three surface properties (γ^{LW}, γ⁺ and γ⁻) of the unknown solid/liquid. Results of these calculations are presented in Table 3.

TABLE 3
Surface energy characterization for coating material and
repellent materials

| | Total | Polar | Dispersive | Acidic | Basic |
|---|---|---|---|---|---|
| | (mN/m) | (mN/m) | (mN/m) | (mN/m) | (mN/m) |
| Material A | 47.5 | 21.3 | 26.2 | 4.7 | 24.1 |
| Parowax | 26.7 | 5.8 | 20.9 | 2.9 | 2.9 |
| AccuBlend M-300 | 32 | 11.9 | 20.1 | 5.8 | 6.1 |
| Microblend | 37.2 | 17 | 20.2 | 14.6 | 4.9 |

To test the correlation of de-wetting (or repellent) performance with the surface energy properties the three repellent materials were used to study the de-wetting effect on dummy dies with 240-micron bumps. The top portion of the bumps on the dies were coated with the in such a way as to cover the full surface area of the bumps by pressing the bumped side of the wafer against a paper pad saturated with the paraffin wax at 135° C. Samples were prepared using each of the three waxes, Parowax, Accu-blend M-300, and Microblend. The depth of the press was controlled by shims. After cooling at room temperature, the wax hardened to form a smooth coating on the bumps. Next, Material A was spin coated on each of these dies. The spin coating profile included a spread cycle at 350 rpm for 15 seconds followed by a spin cycle at 800 rpm for 5 seconds. Solvent was removed from the coating material by a B-stage step at 135° C. for 20 minutes, resulting in the formation of a hardened non-tacky coating.

The extent of de-wetting of the coating material from the solder bump tips was measured by calculating the bump area exposed via digital gray scale analysis, based on a bump diameter of 240 microns, for a sample area of 22 bumps. The average % bump area exposed was as follows: Parowax 97.4%, Accublend M-300 53%, and Microblend <1%.

The relative de-wetting performance matched the trend in surface energy (lowest to highest), with the lower surface energy wax having the most de-wetting effect. The paraffin wax (Parowax) had the greatest difference in total surface energy compared to the Material A. The least difference between the surface energy of the wax and Material A was found to be with the Microblend.

Since the dispersive components of the surface energies were similar for all the repellent materials tested, the difference in de-wetting performance was clearly due to the more acidic character of the Microblend interacting with the comparatively more basic character of Material A. In comparison, the Parowax and Accublend lacked the high acidic component in their surface energy and therefore were more effective in repelling the comparatively basic Material A.

Many modifications and variations of this invention can be made without departing from its spirit and scope, as will be apparent to those skilled in the art. The specific embodiments described herein are offered by way of example only, and the invention is to be limited only by the terms of the appended claims, along with the full scope of equivalents to which such claims are entitled.

What is claimed:

1. A process for coating the active side of a semiconductor wafer which has solder bumps deposited thereon comprising:
(a) providing a semiconductor wafer having a front side which is active and has solder bumps deposited thereon and a back side opposed to the front side,
(b) applying a repellent material to a top portion of the solder bumps,
(c) coating the front side of the wafer with coating material,
(d) hardening the coating material, and
(e) optionally, removing the repellent material from the bump.

2. The process of claim 1 in which the repellent material is a wax.

3. The process of claim 1 in which the repellent material is applied to between 5 and 100% of the overall solder bump height.

4. The process of claim 1 in which there is at least a 5 mN/m differential between the surface energy of the repellent material and the surface energy of the coating material.

5. The process of claim 1 in which the repellent material is non-polar and the coating material is polar.

6. The process of claim 1 in which the repellent material has a melting point of −40° C. to 300° C.

7. The process of claim 1 in which the repellent material is applied by dipping the tops of the bumps on the bumped wafer into a pad that is saturated with the repellent material.

8. The process of claim 1 in which the repellent material is applied by dipping the tops of the solder bumps on the wafer into a reservoir of repellent material in a liquid state.

9. The process of claim 1 in which the coating material is applied by spin coating.

10. The process of claim 1 in which the coating material is applied by stencil printing.

11. The process of claim 1 in which the coating material is selected from the group consisting of bismaleimide, epoxy, acrylate, and combinations of those.

12. The process of claim 1 in which the coating material is B-stageable.

13. The process of claim 1 in which the coating material is UV-curable.

14. A semiconductor wafer having a front side and a back side opposed to the back side wherein the front side is a) active, b) bumped with solder bumps, and c) coated by the process of:
i) applying a repellent material to a top portion of the solder bumps,
ii) coating the front side of the wafer with coating material,
iii) hardening the coating material, and
iv) optionally, melting and/or evaporating the repellent material.
